(19) United States
(12) Patent Application Publication
(10) Pub. No.: US 2023/0171950 A1
(43) Pub. Date: Jun. 1, 2023

(54) SEMICONDUCTOR DEVICE

(71) Applicant: Samsung Electronics Co., Ltd., Suwon-si (KR)

(72) Inventors: Sunguk Jang, Hwaseong-si (KR); Kongsoo Lee, Hwaseong-si (KR); Sahwan Hong, Suwon-si (KR)

(21) Appl. No.: 17/940,323

(22) Filed: Sep. 8, 2022

(30) Foreign Application Priority Data
Nov. 29, 2021 (KR) 10-2021-0167055

(51) Int. Cl. H01L 27/108

(52) U.S. Cl. CPC H01L 27/10814

(57) ABSTRACT

A semiconductor device includes a plurality of semiconductor patterns stacked to be spaced apart from each other in a first direction, perpendicular to an upper surface of a substrate, and extending in a second direction, parallel to the upper surface of the substrate, a plurality of first conductive patterns extending in a third direction, perpendicular to the first direction and the second direction, on the plurality of semiconductor patterns, a plurality of second conductive patterns extending in the first direction on the substrate, a plurality of capacitors electrically connected to the plurality of semiconductor patterns, respectively, and at least one epitaxial layer disposed to be in contact with at least one of both end surfaces of at least one of the plurality of semiconductor patterns and including an impurity.

### CROSS-REFERENCE TO RELATED APPLICATION(S)

This application claims benefit of priority under 35 U.S.C. § 119 to Korean Patent Application No. 10-2021-0167055, filed on Nov. 29, 2021, in the Korean Intellectual Property Office, the disclosure of which is incorporated herein by reference in its entirety.

### BACKGROUND

The present inventive concept relates to a semiconductor device.

Electronic devices have become smaller and more highly efficient according to the development of the electronics industry and user demand. Accordingly, semiconductor devices used in electronic devices are also required to be highly integrated and to have higher performance. In the case of two-dimensional (2D) or planar semiconductor devices, a degree of integration thereof is mainly determined by an area occupied by a unit memory cell, and thus, the 2D or planar semiconductors are greatly affected by a level of fine pattern forming technology. However, since ultra-expensive equipment is required for pattern miniaturization, the degree of integration of the 2D semiconductor device is increasing, but is still limited. Accordingly, 3D semiconductor memory devices including three-dimensionally arranged memory cells have been proposed.

### SUMMARY

An aspect of the present inventive concept is to provide a semiconductor device having improved electrical characteristics and reliability.

According to an aspect of the present inventive concept, a semiconductor device includes: a plurality of semiconductor patterns stacked to be spaced apart from each other in a first direction, perpendicular to an upper surface of a substrate, and extending in a second direction, parallel to the upper surface of the substrate; a plurality of first conductive patterns extending in a third direction, perpendicular to the first direction and the second direction, on the plurality of semiconductor patterns; a plurality of second conductive patterns extending in the first direction on the substrate; a plurality of capacitors, each of the plurality of capacitors electrically connected to a corresponding one of the plurality of semiconductor patterns; and at least one epitaxial layer disposed to be in contact with at least one of both end surfaces of at least one of the plurality of semiconductor patterns and including an impurity.

According to an aspect of the present inventive concept, a semiconductor device includes: a plurality of structures and a plurality of first insulating layers alternately stacked on a substrate; and a vertical conductive pattern extending vertically in a first direction, perpendicular to an upper surface of the substrate, on the substrate, wherein each of the plurality of structures includes: a capacitor including a capacitor electrode and a dielectric layer; a semiconductor pattern including a first impurity region electrically connected to the vertical conductive pattern, a second impurity region electrically connected to the capacitor electrode, and a channel region between the first impurity region and the second impurity region; a gate electrode disposed between the channel region of the semiconductor pattern and the first insulating layer and intersecting the vertical conductive pattern to extend in a second direction, parallel to the upper surface of the substrate; at least one epitaxial layer disposed to be in contact with at least one of the first impurity region and the second impurity region of the semiconductor pattern and including an impurity having a concentration greater than a concentration of the first impurity region and the second impurity region; a gate dielectric layer between the gate electrode and the semiconductor pattern; a gate capping layer between the gate electrode and the vertical conductive pattern; and a second insulating layer between the gate electrode and the capacitor electrode.

According to an aspect of the present inventive concept, a semiconductor device includes: a plurality of semiconductor patterns extending in a first direction parallel to an upper surface of a substrate and stacked to be spaced apart from each other on the substrate; a conductive pattern intersecting the plurality of semiconductor patterns and extending in a second direction, perpendicular to the first direction; a capacitor electrically connected to the semiconductor pattern; an epitaxial layer extending from at least one end surface of the semiconductor pattern and having a vertical thickness thicker than a vertical thickness of the semiconductor pattern; and a metal-semiconductor compound layer surrounding a surface of the epitaxial layer.

### BRIEF DESCRIPTION OF DRAWINGS

The above and other aspects, features, and advantages of the present inventive concept will be more clearly understood from the following detailed description, taken in conjunction with the accompanying drawings, in which like numerals refer to like elements throughout. In the drawings:

FIG. 1 is a simplified circuit diagram illustrating a cell array of a semiconductor device, according to example embodiments;

FIG. 2 is a schematic plan view of a semiconductor device, according to example embodiments;

FIG. 3 is a schematic cross-sectional view of a semiconductor device, according to example embodiments;

FIGS. 4A and 4B are partially enlarged views of a semiconductor device, according to example embodiments;

FIGS. 5A and 5B are schematic cross-sectional views of semiconductor devices, according to example embodiments;

FIGS. 6A to 7B are schematic cross-sectional views of semiconductor devices, according to example embodiments;

FIG. 8 is a simplified circuit diagram illustrating a cell array of a semiconductor device, according to example embodiments;

FIG. 9 is a schematic plan view of a semiconductor device, according to example embodiments;

FIG. 10 is a schematic cross-sectional view of a semiconductor device, according to example embodiments; and

FIGS. 11 to 16 are cross-sectional views illustrating a method of manufacturing a semiconductor device, according to example embodiments.

### DETAILED DESCRIPTION

Hereinafter, example embodiments of the present inventive concept will be described with reference to the accompanying drawings.

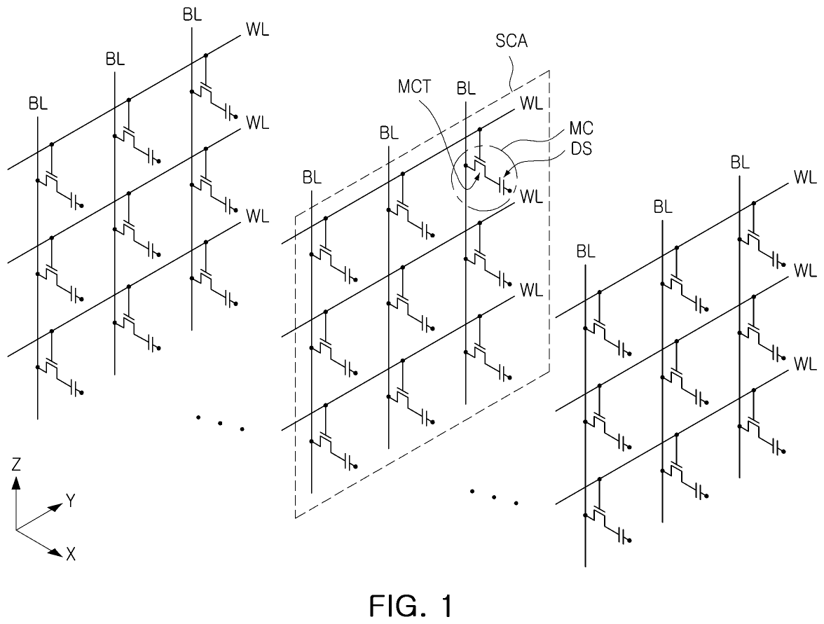

FIG. 1 is a simplified circuit diagram illustrating a cell array of a semiconductor device according to example embodiments.

Referring to FIG. 1, a cell array of a semiconductor device according to example embodiments may include a plurality of sub-cell arrays SCA. The plurality of sub cell arrays SCA may be arranged in an X-direction. Each of the plurality of sub-cell arrays SCA may include a plurality of bit lines BL, a plurality of word lines WL, and a plurality of memory cells MC. The memory cell MC may include a memory cell transistor MCT and a data storage element DS. A single memory cell MC may be disposed between one word line WL and one bit line BL. The cell array of the semiconductor device may correspond to a memory cell array of a dynamic random access memory (DRAM) device.

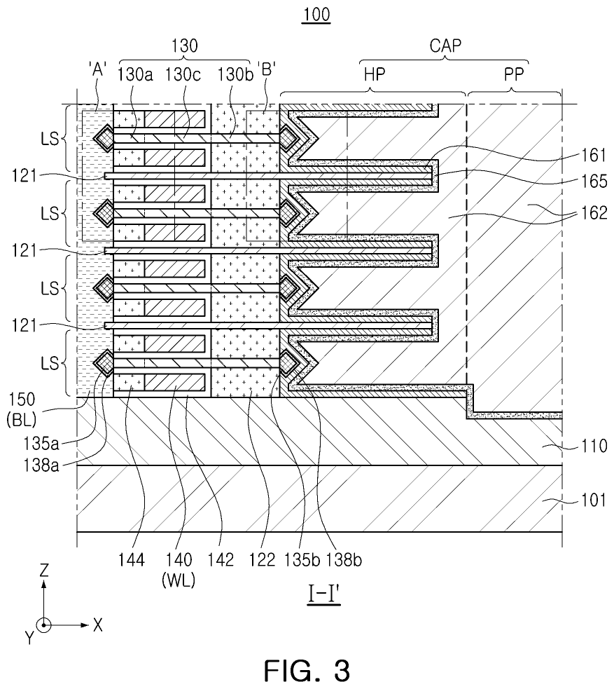

The word lines WL may extend in a Y-direction. The word lines WL in one sub cell array SCA may be spaced apart from each other in a Z-direction. The bit lines BL may extend in the Z-direction. The bit lines BL in one sub cell array SCA may be spaced apart from each other in the Y-direction. The word lines WL and the bit lines BL may be conductive patterns (e.g., metal lines) respectively disposed on a substrate (e.g., substrate 101 of FIG. 3) and extend in one direction.

The memory cell transistor MCT may include a gate, a source, and a drain. The gate may be connected to the word line WL, the source may be connected to the bit line BL, and the drain may be connected to the data storage element DS. The data storage element DS may include a capacitor including lower and upper electrodes and a dielectric layer.

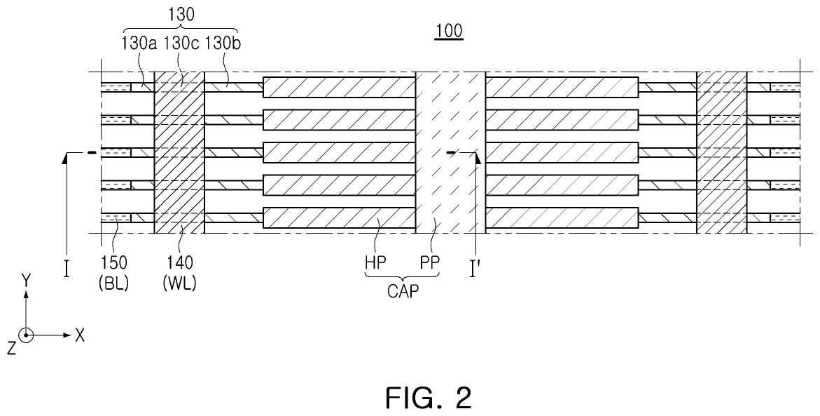

FIG. 2 is a schematic plan view of a semiconductor device according to example embodiments. FIG. 2 exemplarily illustrates a structure of a pair of sub-cell arrays adjacent to each other described with reference to FIG. 1.

FIG. 3 is a schematic cross-sectional view of a semiconductor device according to example embodiments. FIG. 3 is a cross-sectional view of the semiconductor device of FIG. 2, taken along line I-I′.

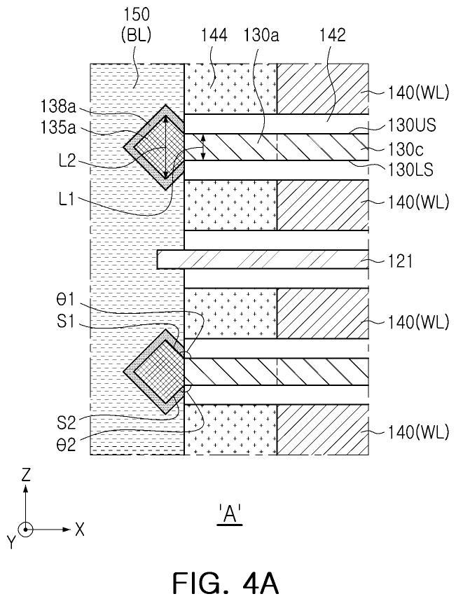

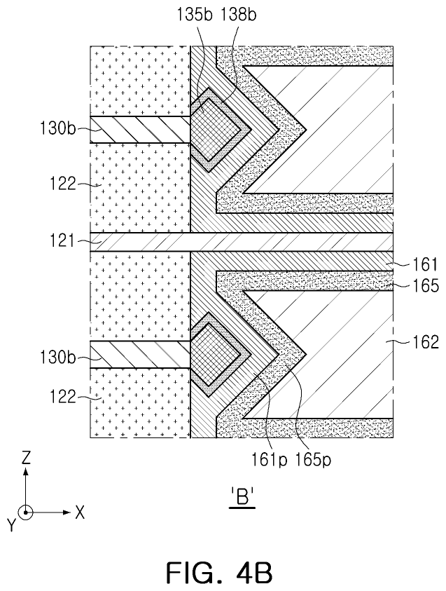

FIGS. 4A and 4B are partially enlarged views of a semiconductor device according to example embodiments. FIG. 4A is an enlarged view of region ‘A’ of FIG. 3, and FIG. 4B is an enlarged view of region ‘B’ of FIG. 3.

Referring to FIGS. 2 to 4B, a semiconductor device 100 may include a substrate 101, a lower structure 110 on the substrate 101, a plurality of structures LS alternately stacked on the substrate 101, a plurality of first insulating layers 121, and a plurality of second conductive patterns 150 spaced apart from each other. Each of the plurality of structures LS may include a semiconductor pattern 130 extending in the X-direction, a first conductive pattern 140 intersecting the semiconductor pattern 130 and extending in the Y-direction, perpendicular to the X-direction, epitaxial layers 135a and 135b disposed at both ends of the semiconductor pattern 130, metal-semiconductor compound layers 138a and 138b surrounding surfaces of the epitaxial layers 135a and 135b, respectively, a gate dielectric layer 142 between the semiconductor pattern 130 and the first conductive pattern 140, a gate capping layer 144 between the first conductive pattern 140 and the second conductive pattern 150, a first electrode 161 of a capacitor CAP, and a second insulating layer 122 between the first conductive pattern 140 and the first electrode 161. The gate dielectric layer 142 may contact the semiconductor pattern 130, the first conductive pattern 140, and the gate capping layer 144. The capacitor CAP may further include a dielectric layer 165 on the first electrode 161 and a second electrode 162 on the dielectric layer 165. The dielectric layer 165 may be between and may contact the first and second electrodes 161 and 162. The X-direction and the Y-direction may be perpendicular to each other and parallel to an upper surface of the substrate 101. The Z-direction may be perpendicular to the X-direction and the Y-direction and may be perpendicular to the upper surface of the substrate 101. As used herein, the term “contact” refers to a direct connection (i.e., touching) unless the context indicates otherwise.

The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may further include impurities. The substrate 101 may include a silicon substrate, a silicon on insulator (SOI) substrate, a germanium substrate, a germanium on insulator (GOI) substrate, a silicon-germanium substrate, or a substrate including an epitaxial layer.

The lower structure 110 may be disposed on the substrate 101. The plurality of structures LS and the plurality of first insulating layers 121 may be stacked on the lower structure 110. The lower structure 110 may include a device region on the substrate 101 and an insulating region covering the device region. The insulating region may be formed of insulating layers including an insulating material, for example, at least one of silicon oxide, silicon nitride, silicon oxynitride, and silicon oxycarbide.

The plurality of structures LS and the plurality of first insulating layers 121 may form a stack structure on the substrate 101. The plurality of structures LS may be disposed between the plurality of first insulating layers 121 and may be spaced apart from each other in the Z-direction by the plurality of first insulating layers 121. The first insulating layer 121 may extend in the X-direction, and an end portion thereof may extend into the second conductive pattern 150. The second insulating layer 122 may be disposed between the first insulating layer 121 and the semiconductor pattern 130 and between the first conductive pattern 140 and the capacitor CAP. Each of the first insulating layer 121 and the second insulating layer 122 may include an insulating material, for example, at least one of silicon oxide, silicon nitride, silicon oxynitride, and silicon oxycarbide. The first insulating layer 121 may extend horizontally longer than the second insulating layer 122. A thickness of the second insulating layer 122 may be thicker than a thickness of the first insulating layer 121. As used herein, the term “thickness” may refer to the thickness or length measured in a direction perpendicular to a top surface of the substrate 101 (e.g., a Z-direction).

The semiconductor pattern 130 may be disposed on the substrate 101 and may extend horizontally in the X-direction. A plurality of semiconductor patterns 130 may be stacked to be spaced apart from each other in the Z-direction and may be arranged in plurality in the Y-direction. A plurality of semiconductor patterns 130 arranged in the Z-direction may be disposed between the plurality of first insulating layers 121. The semiconductor pattern 130 may have a line shape, a bar shape, or a pillar shape intersecting the first conductive pattern 140 and extending lengthwise in the X-direction. The semiconductor pattern 130 may include a semiconductor material, for example, silicon, germanium, or silicon-germanium.

The semiconductor pattern 130 may include a first impurity region 130a, a second impurity region 130b, and a channel region 130c. The first impurity region 130a may contact the first epitaxial layer 135a and may be electrically connected to the second conductive pattern 150. The second impurity region 130b may contact the second epitaxial layer 135b and may be electrically connected to the first electrode 161 of the capacitor CAP. A length of the second impurity region 130b in the X-direction may be longer than a length of the first impurity region 130a in the X-direction, but is not limited thereto. The channel region 130c may be disposed between the first impurity region 130a and the second impurity region 130b. The channel region 130c may overlap the first conductive pattern 140 in the Z-direction.

The first impurity region 130a and the second impurity region 130b may be formed by doping impurities into the semiconductor pattern 130 or performing an ion implantation process, or may be formed as impurities included in the first epitaxial layer 135a and the second epitaxial layer 135b are diffused into the semiconductor pattern 130. The first impurity region 130a and the second impurity region 130b may have n-type or p-type conductivity.

A portion of the first impurity region 130a may correspond to a source region of the memory cell transistor MCT of FIG. 1, a portion of the second impurity region 130b may correspond to a drain region of the memory cell transistor MCT of FIG. 1, and the channel region 130c may correspond to a channel of the memory cell transistor MCT of FIG. 1. A portion of the first impurity region 130a may provide a first contact region for directly connecting the source region of the memory cell transistor MCT to the second conductive pattern 150, that is, the bit line BL, and a portion of the second impurity region 130b may provide a second contact region for directly connecting the drain region of the memory cell transistor MCT to the data storage element DS, that is, the capacitor CAP.

The epitaxial layers 135a and 135b may include semiconductor layers grown by performing an epitaxial growth process from the semiconductor pattern 130. The semiconductor layer may include an impurity, and the impurity may include at least one of Ph, As, B, C, and Ga. The epitaxial layers 135a and 135b may have a facet shape grown according to a crystal direction of a semiconductor material layer forming the semiconductor pattern 130. For example, the epitaxial layers 135a and 135b may have a cross-sectional shape of a triangle, a quadrangle, a pentagon, a hexagon, an octagon, a rhombus, a circle, or an ellipse. A facet of the epitaxial layers 135a and 135b may be a silicon (111) crystal plane, but is not limited thereto.

The first epitaxial layer 135a, among the epitaxial layers 135a and 135b, is connected to an upper surface 130US and a lower surface 130LS of the semiconductor pattern 130 and may have inclined surfaces S1 and S2 with respect to the upper surface 130US and the lower surface 130LS of the semiconductor pattern 130, respectively. Angle θ1 between the inclined surface Si and the upper surface 130US of the semiconductor pattern 130 may be an obtuse angle, and angle θ2 between the inclined surface S2 and the lower surface 130LS of the semiconductor pattern 130 may be an obtuse angle. The inclined surfaces S1 and S2 may be inclined with respect to end surfaces of the semiconductor pattern 130. In the Z-direction, a length (or a vertical thickness) L2 between an upper end and a lower end of the epitaxial layer 135a may be longer than a length L1 (or a vertical thickness) between the upper surface 130US and the lower surface 130LS of the semiconductor pattern 130. Similarly, the second epitaxial layer 135b, among the epitaxial layers 135a and 135b, may also have a shape corresponding to that of the first epitaxial layer 135a. The upper ends of the epitaxial layers 135a and 135b may be located on a level higher than the upper surface 130US of the semiconductor pattern 130 with respect to the upper surface of the substrate 101. The lower ends of the epitaxial layers 135a and 135b may be located on a level lower than the lower surface 130LS of the semiconductor pattern 130 with respect to the upper surface of the substrate 101. In the Z-direction, a length (or a vertical thickness) L2 between an upper end and a lower end of the second epitaxial layer 135b may be longer than the length L1 between the upper surface 130US and the lower surface 130LS of the semiconductor pattern 130.

The epitaxial layers 135a and 135b may include a first epitaxial layer 135a and a second epitaxial layer 135b in contact with both end surfaces of one semiconductor pattern 130, respectively. The first epitaxial layer 135a may be disposed between the first impurity region 130a and the second conductive pattern 150, and the second epitaxial layer 135b may be disposed between the second impurity region 130b and the first electrode 161 of the capacitor CAP. The first epitaxial layer 135a may extend from the first impurity region 130a and may overlap the second conductive pattern 150 in the Z-direction. The second epitaxial layer 135b may extend from the second impurity region 130b and may overlap the first electrode 161 of the capacitor CAP in the Z-direction.

Impurities included in the epitaxial layers 135a and 135b may include at least one of Ph, As, B, C, and Ga. Concentrations of impurities included in the epitaxial layers 135a and 135b may be greater than an impurity concentration of the first impurity region 130a and an impurity concentration of the second impurity region 130b. For example, the concentration of impurities included in the epitaxial layers 135a and 135b may be in a range of about 10²⁰/cm³ to about 5×10²¹/cm³.

In the absence of the epitaxial layers 135a and 135b, lateral doping should be directly performed with the semiconductor pattern 130. As the integration of the semiconductor device in the Z-direction increases, the process difficulty increases and it is difficult to control the process distribution. According to an exemplary embodiment of the present inventive concept, since the doping process is performed in-situ while forming the epitaxial layers 135a and 135b, the doping process may be performed more smoothly than when the epitaxial layers 135a and 135b are absent, and thus, the doping concentration may be more easily controlled. Accordingly, electrical characteristics and reliability of the semiconductor device may be improved. For example, when the epitaxial layers 135a and 135b are present, the doping concentration may be increased by about 10 times or more than when the epitaxial layers 135a and 135b are not present. Also, since the semiconductor device 100 includes the epitaxial layers 135a and 135b, the metal-semiconductor compound layers 138a and 138b may be disposed in a wider region, and since a contact area with the second conductive pattern 150 or the first electrode 161 is increased, electrical resistance may be reduced.

The metal-semiconductor compound layers 138a and 138b may be disposed to surround surfaces of the epitaxial layers 135a and 135b, respectively. Inner surfaces of the metal-semiconductor compound layers 138a and 138b may contact respective outer surfaces of the epitaxial layers 135a and 135b. The metal-semiconductor compound layers 138a and 138b may have a shape corresponding to the surface of the epitaxial layers 135a and 135b. For example, the metal-semiconductor compound layers 138a and 138b may have inclined side surfaces corresponding to the inclined side surfaces of the epitaxial layers 135a and 135b. The metal-semiconductor compound layers 138a and 138b may include, for example, metal silicide, metal germanide, or metal silicide-germanide. In the metal-semiconductor compound layers 138a and 138b, the metal may be titanium (Ti), nickel (Ni), tantalum (Ta), cobalt (Co), or tungsten (W), and the semiconductor may be silicon (Si), germanium (Ge), or silicon germanium (SiGe). For example, the metal-semiconductor compound layers 138a and 138b may include at least one of cobalt silicide (CoSi), titanium silicide (TiSi), nickel silicide (NiSi), and tungsten silicide (WSi).

The metal-semiconductor compound layers 138a and 138b may include a first metal-semiconductor compound layer 138a covering a surface of the first epitaxial layer 135a and a second metal-semiconductor compound layer 138b covering a surface of the second epitaxial layer 135b. Inner surfaces of the second conductive pattern 150 may contact outer surfaces of the first metal-semiconductor compound layer 138a, and inner surfaces of the first electrode 161 may contact outer surfaces of the second metal-semiconductor compound layer 138b.

By disposing the first metal-semiconductor compound layer 138a between the first epitaxial layer 135a including a semiconductor material and the second conductive pattern 150 including a metal material, an ohmic contact may be formed to lower electrical resistance. By disposing the second metal-semiconductor compound layer 138b between the second epitaxial layer 135b including a semiconductor material and the first electrode 161 including a metal material, an ohmic contact may be formed to lower electrical resistance.

The first conductive pattern 140 may be disposed on the substrate 101 and may extend horizontally in the Y-direction. A plurality of first conductive patterns 140 may be stacked and spaced apart from each other in the Z-direction and may be arranged in plurality in the X-direction. The first conductive pattern 140 may be disposed between the channel region 130c of the semiconductor pattern 130 and the first insulating layer 121. The first conductive pattern 140 may be disposed on the upper surface 130US and the lower surface 130LS of the semiconductor pattern 130. The first conductive pattern 140 may have a line shape, a bar shape, or a pillar shape intersecting the second conductive pattern 150 and extending in the Y-direction. Although not illustrated, the plurality of first conductive patterns 140 stacked in the Z-direction in one memory cell may extend to have different lengths in the Y-direction to provide a contact region in which a top surface thereof is exposed.

The first conductive pattern 140 may include a conductive material, and the conductive material may include at least one of a doped semiconductor material (e.g., doped silicon, doped germanium, etc.), a conductive metal nitride (e.g., titanium nitride, tantalum nitride, tungsten nitride, etc.), a metal (e.g., tungsten, titanium, tantalum, cobalt, aluminum, ruthenium, etc.), and a metal-semiconductor compound (e.g., tungsten silicide, cobalt silicide, titanium silicide, etc.). The first conductive pattern 140 may be the word line WL described with reference to FIG. 1, and may also be referred to as a “gate electrode”.

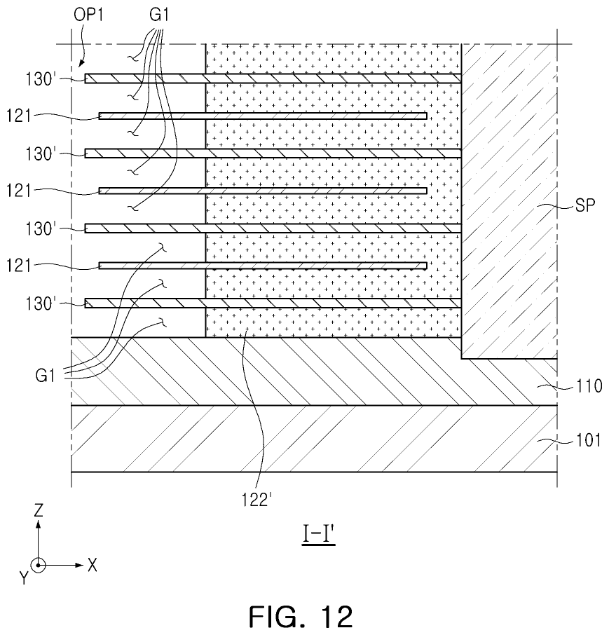

The gate dielectric layer 142 may be disposed between the first conductive pattern 140 and the semiconductor pattern 130. The gate dielectric layer 142 may be formed to have a substantially conformal thickness in an internal space of a gap region (refer to “G1” of FIG. 12) formed as the second insulating layer 122 is etched from a side surface between the first insulating layers 121 adjacent to each other. The gate dielectric layer 142 may include silicon oxide, silicon nitride, or a high-k material. The high-k material may refer to a dielectric material having a higher dielectric constant than silicon oxide (SiO₂). The high-k material may be any one of, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃).

The gate capping layer 144 may be disposed to fill a region in which the first conductive pattern 140 is partially removed from a side surface thereof. For example, the side surface of the gate capping layer 144 may contact the side surface of the first conductive pattern 140, and upper and lower surfaces of the gate capping layer 144 may be covered by the gate dielectric layer 142. The gate capping layer 144 may electrically insulate the first conductive pattern 140 and the second conductive pattern 150.

The second conductive pattern 150 may extend vertically on the substrate 101 in the Z-direction. A plurality of second conductive patterns 150 may be arranged in the Y-direction. The second conductive pattern 150 may be disposed adjacent to the first impurity region 130a and the first end surface of the semiconductor pattern 130. The second conductive pattern 150 may have an inclined inner surface facing the inclined side surfaces of the first epitaxial layer 135a. A plurality of semiconductor patterns 130 stacked in the Z-direction may be electrically connected to one second conductive pattern 150. The second conductive pattern 150 may have a line shape, a bar shape, or a pillar shape extending in the Z-direction. Although not illustrated, the semiconductor device may further include an upper wiring disposed on the second conductive pattern 150, connected to the second conductive pattern 150, and extending in the X-direction. The second conductive pattern 150 may include at least one of a doped semiconductor material, a conductive metal nitride, a metal, and a metal-semiconductor compound. The second conductive pattern 150 may be the bit line BL described with reference to FIG. 1.

The capacitor CAP may be disposed adjacent to the second impurity region 130b and the second end surface of the semiconductor pattern 130. The capacitor CAP may be electrically connected to the semiconductor pattern 130. The capacitor CAP may include a first electrode 161, a dielectric layer 165 on the first electrode 161, and a second electrode 162 on the dielectric layer 165. As illustrated in FIG. 2, the capacitor CAP may include a horizontal portion HP and a vertical plate portion PP in a plan view. The vertical plate portion PP may be a portion in which a portion of the second electrode 162 shared by a pair of adjacent memory cells is disposed. As illustrated in FIG. 3, the capacitor CAP may have a cylinder shape, but is not limited thereto, and may have a pillar shape in embodiments.

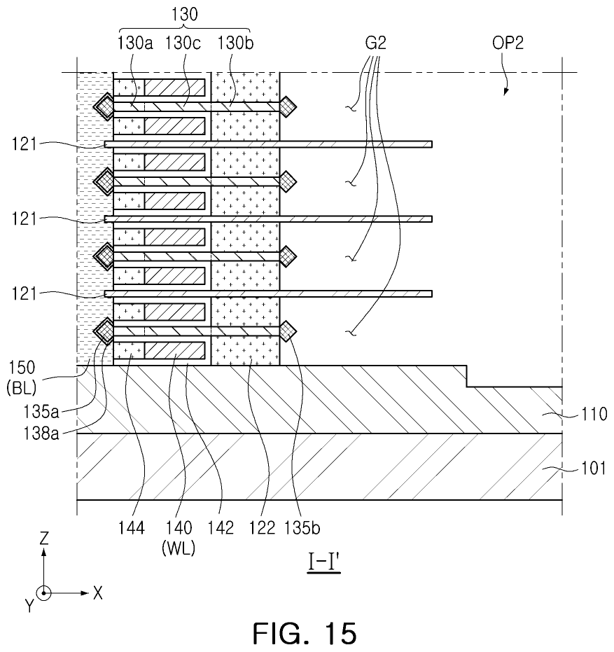

The first electrode 161 may be formed to have a substantially conformal thickness in the internal space of the gap region (refer to gap region G2 of FIG. 15) formed by etching the second insulating layer 122 from the side surface. The first electrode 161 may be disposed on the horizontal portion HP. The first electrode 161 may be in a state in which a node is separated for each structure LS by removing a portion on a side surface of the first insulating layer 121 after depositing a conductive material. The first electrode 161 may be in contact with the second metal-semiconductor compound layer 138b and may include a portion 161p protruding toward the second electrode 162 to correspond to a shape of the second epitaxial layer 135b. The protruding portion 161p of the first electrode may cover an inclined side surface of the second epitaxial layer 135b. The first electrode 161 may include at least one of a doped semiconductor material, a conductive metal nitride, a metal, and a metal-semiconductor compound.

The dielectric layer 165 may conformally cover the first electrode 161. The dielectric layer 165 may cover the protruding portion 161p of the first electrode 161 and may include a portion 165p protruding toward the second electrode 162. The dielectric layer 165 may include at least one of high-k materials such as zirconium oxide (ZrO₂), aluminum oxide (Al₂O₃), or hafnium oxide (Hf₂O₃).

The second electrode 162 may cover the dielectric layer 165 and may be disposed at the horizontal portion HP and the vertical plate portion PP. The second electrode 162 may continuously extend from the horizontal portion HP to the vertical plate portion PP. The second electrode 162 may include a portion concavely recessed inward from the horizontal portion HP by the protruding portion 161p of the first electrode 161 and the protruding portion 165p of the dielectric layer 165. The second electrode 162 may include at least one of a doped semiconductor material, a conductive metal nitride, a metal, and a metal-semiconductor compound.

Capacitance of the capacitor CAP may be increased by increasing a contact area between the first and second electrodes 161 and 162 and the dielectric layer 165. In particular, since the second epitaxial layer 135b is disposed between the semiconductor pattern 130 and the capacitor CAP, an inclined surface may also be formed between the first and second electrodes 161 and 162 and the dielectric layer 165 to correspond to the inclined side surface of the second epitaxial layer 135b to further increase a contact area, thereby further increasing the capacitance of the capacitor CAP.

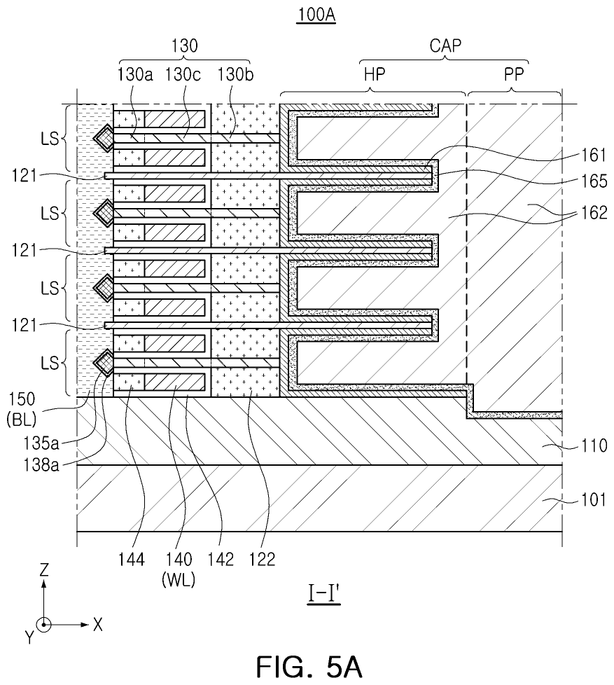

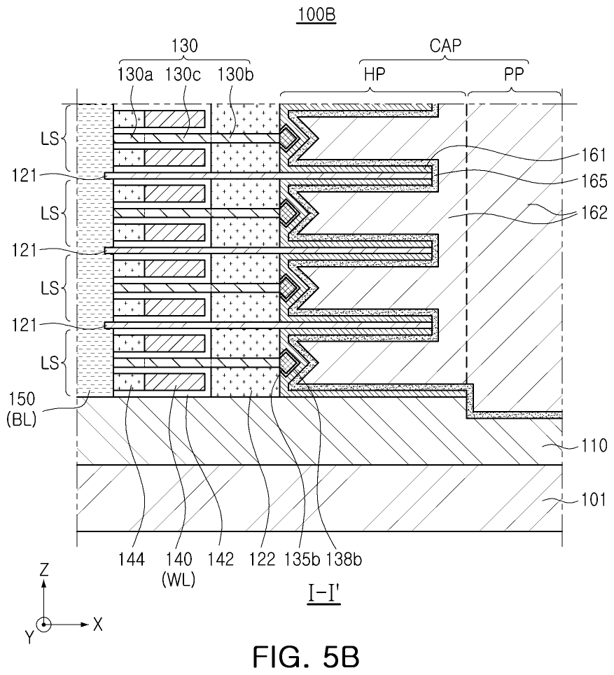

FIGS. 5A and 5B are schematic cross-sectional views of semiconductor devices according to example embodiments. FIGS. 5A and 5B illustrate regions corresponding to FIG. 3.

Referring to FIG. 5A, a structure LS of a semiconductor device 100A may include a first epitaxial layer 135a in contact with the first impurity region 130a of the semiconductor pattern 130 and a first metal-semiconductor compound layer 138a surrounding a surface of first epitaxial layer 135a, and the second epitaxial layer 135b and the second metal-semiconductor compound layer 138b may not be disposed in the second impurity region 130b of the semiconductor pattern 130. In other words, the second impurity region 130b of the semiconductor pattern 130 may directly contact the first electrode 161 of the capacitor CAP.

Referring to FIG. 5B, a structure LS of a semiconductor device 100B may include a second epitaxial layer 135b in contact with the second impurity region 130b of the semiconductor pattern 130 and a second metal-semiconductor compound layer 138b surrounding a surface of the second epitaxial layer 135b, and the first epitaxial layer 135a and the first metal-semiconductor compound layer 138a may not be disposed in the first impurity region 130a of the semiconductor pattern 130. In other words, the first impurity region 130a of the semiconductor pattern 130 may directly contact the second conductive pattern 150.

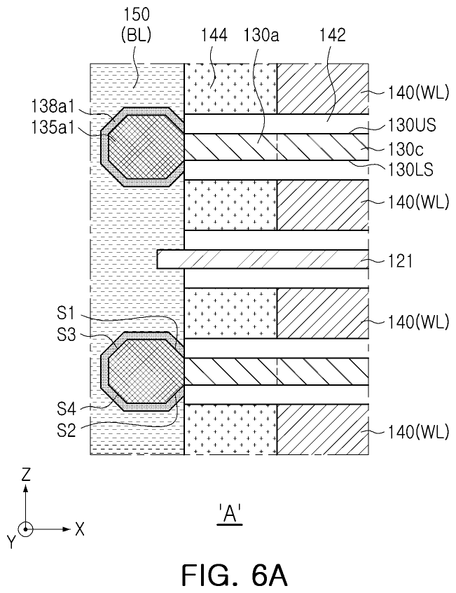

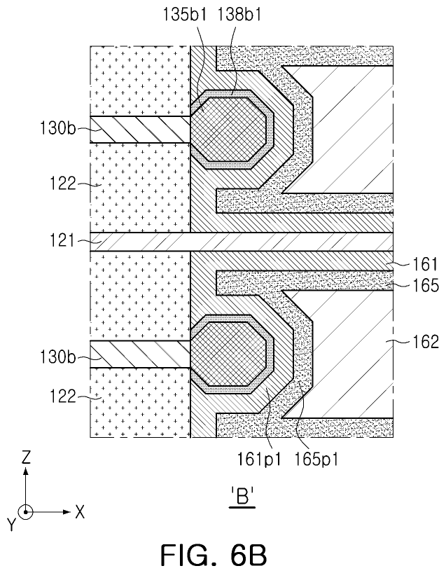

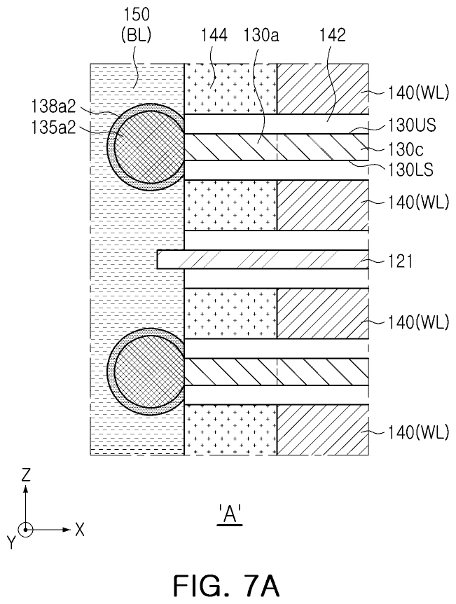

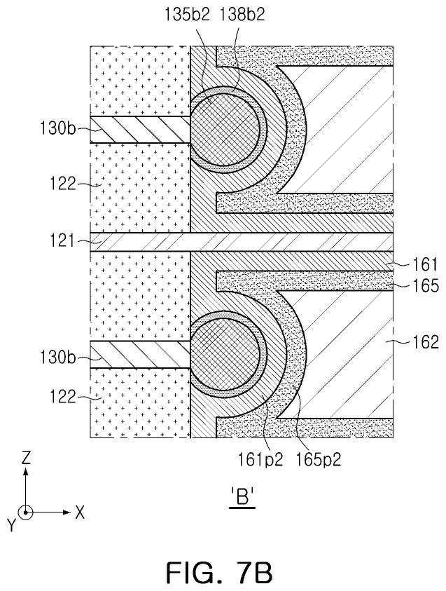

FIGS. 6A to 7B are schematic cross-sectional views of semiconductor devices according to example embodiments. FIGS. 6A and 7A illustrate a region corresponding to FIG. 4A, and FIGS. 6B and 7B illustrate a region corresponding to FIG. 4B.

Referring to FIG. 6A, a first epitaxial layer 135a1 may have an octagonal cross-sectional shape. The first metal-semiconductor compound layer 138a1 may have a shape corresponding to a cross-sectional shape of the first epitaxial layer 135a1. The first epitaxial layer 135a1 may include an upper surface, both side surfaces, a lower surface, inclined surfaces S1 and S3 connecting the upper surface and both side surfaces, and inclined surfaces S2 and S4 connecting the lower surface and both sides surfaces.

Referring to FIG. 6B, the second epitaxial layer 135b1 may have an octagonal cross-sectional shape. A second metal-semiconductor compound layer 138b1 may have a shape corresponding to a cross-sectional shape of the second epitaxial layer 135b1. A protruding portion 161p1 of the first electrode 161 and a protruding portion 165p1 of the dielectric layer 165 may also protrude toward the second electrode 162 to correspond to the cross-sectional shape of the second epitaxial layer 135b1.

Referring to FIG. 7A, the first epitaxial layer 135a2 may have a circular or elliptical cross-sectional shape. A diameter (a major axis or a minor axis in the Z-direction in the case of an ellipse) of the first epitaxial layer 135a2 may be greater than a length between the upper and lower surfaces of the semiconductor pattern 130 in the Z-direction. The first metal-semiconductor compound layer 138a2 may include a curved portion to correspond to a cross-sectional shape of the first epitaxial layer 135a2.

Referring to FIG. 7B, the second epitaxial layer 135b2 may have a circular or elliptical cross-sectional shape. A diameter (a major axis or a minor axis in the Z-direction in the case of an ellipse) of the second epitaxial layer 135b2 may be greater than a length between the upper and lower surfaces of the semiconductor pattern 130 in the Z-direction.

The second metal-semiconductor compound layer 138b2 may include a curved portion corresponding to a cross-sectional shape of the second epitaxial layer 135b2. A protruding portion 161p2 of the first electrode 161 and a protruding portion 165p2 of the dielectric layer 165 may also protrude toward the second electrode 162 to correspond to a cross-sectional shape of the second epitaxial layer 135b2, and the protruding portions 161p2 and 165p2 may include a curved portion.

FIGS. 6A to 7B illustrate a cross-sectional shape of an epitaxial layer connected to the semiconductor pattern 130, but a cross-sectional shape of the epitaxial layer may be variously changed according to embodiments.

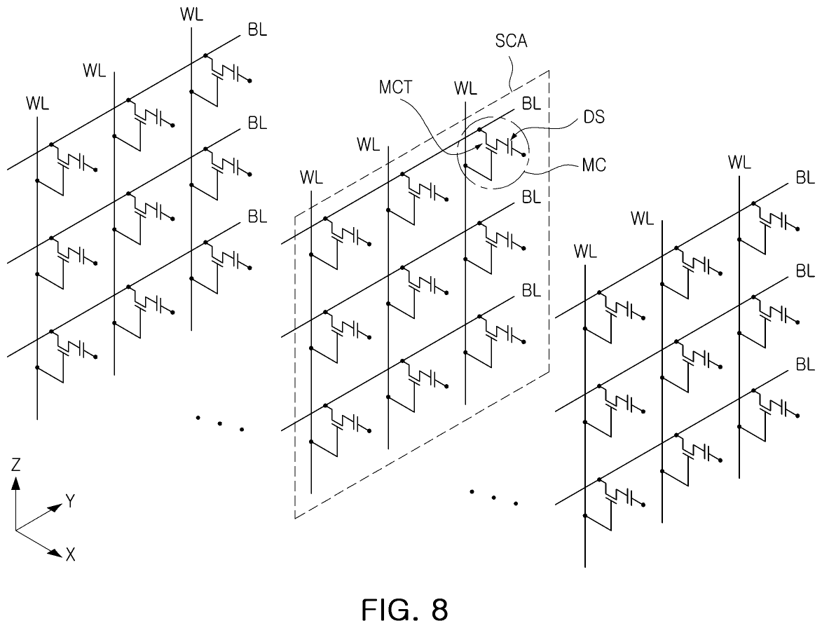

FIG. 8 is a simplified circuit diagram illustrating a cell array of a semiconductor device according to example embodiments.

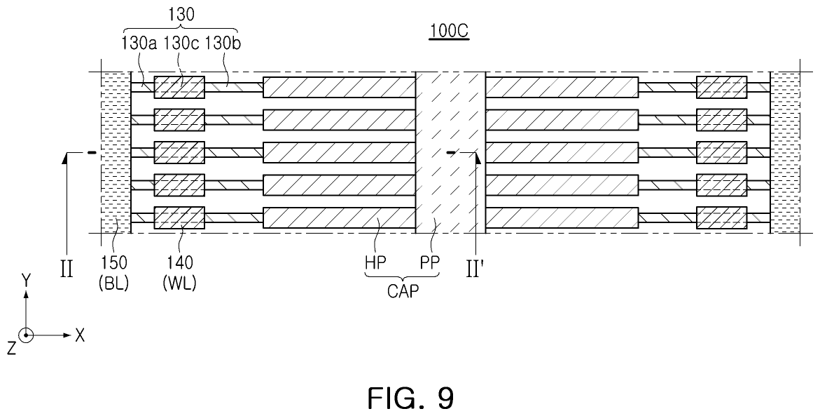

Referring to FIG. 8, a cell array of a semiconductor device according to example embodiments may include a plurality of sub-cell arrays SCA. Each of the plurality of sub-cell arrays SCA may include a plurality of bit lines BL, a plurality of word lines WL, and a plurality of memory cells MC. The memory cell MC may include a memory cell transistor MCT and a data storage element DS. A single memory cell MC may be disposed between one word line WL and one bit line BL. Unlike the circuit of FIG. 1, a plurality of word lines WL may extend in the Z-direction and a plurality of bit lines BL may extend in the Y-direction. A structure of a cell array of a semiconductor device corresponding to the circuit of FIG. 7 is illustrated in FIGS. 8 and 9 below.

FIG. 9 is a schematic plan view of a semiconductor device according to example embodiments.

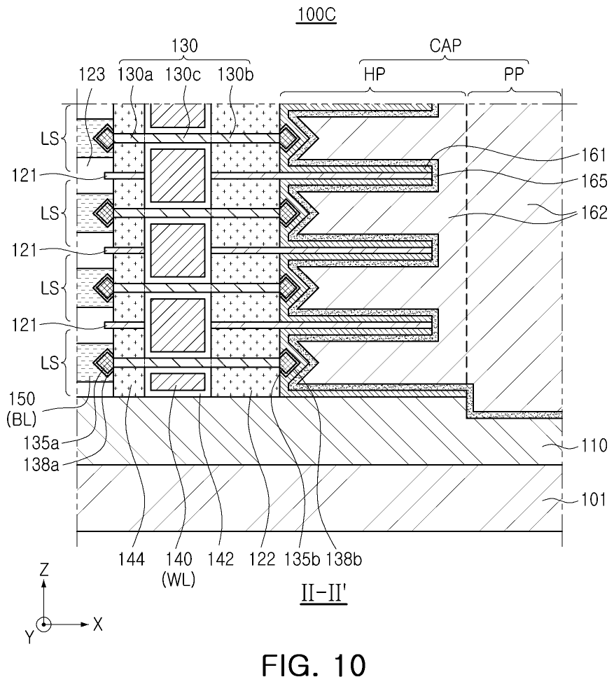

FIG. 10 is a schematic cross-sectional view of a semiconductor device according to example embodiments. FIG. 10 is a cross-sectional view taken along line II-IF of the semiconductor device of FIG. 9.

Referring to FIGS. 9 and 10, in a semiconductor device 100C, the first conductive pattern 140 may extend vertically on the substrate 101 in the Z-direction, and the second conductive pattern 150 may be disposed on the substrate 101 and may extend horizontally in the Y-direction. The first conductive pattern 140 may be disposed to surround upper and lower surfaces of the semiconductor pattern 130 and side surfaces opposite to each other in the Y-direction. The first conductive pattern 140 may be disposed to pass through the first insulating layer 121. A plurality of first conductive patterns 140 may be arranged to be spaced apart from each other in the Y-direction. The semiconductor device 100C may include epitaxial layers 135a and 135b and metal-semiconductor compound layers 138a and 138b, and other components are the same as those described above with reference to FIGS. 3 to 4B, and thus, a description thereof will be omitted. However, in the present inventive concept, the first conductive pattern and the second conductive pattern are defined for convenience of description, and thus may be referred to interchangeably. For example, it may be described that the second conductive pattern 150 is disposed adjacent to the first end surface of the semiconductor pattern 130, and the first conductive pattern 140 intersects the semiconductor pattern 130. In this case, the first epitaxial layer 135a may be described as being disposed between the second conductive pattern 150 and the semiconductor pattern 130.

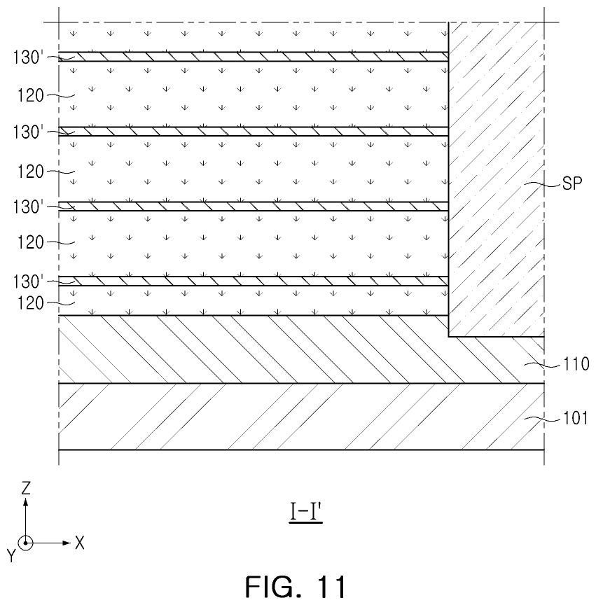

FIGS. 11 to 16 are cross-sectional views illustrating a method of manufacturing a semiconductor device according to example embodiments.

Referring to FIG. 11, a lower structure 110 may be formed on the substrate 101, and a sacrificial layer 120 and a semiconductor layer 130′ may be alternately stacked in the Z-direction to form a stack structure, a patterning process may be performed on the substrate 101 to form trenches passing through the sacrificial layer 120 and the semiconductor layer 130′ and extending in the X-direction, the trenches may be filled with an insulating material layer, and a sacrificial plate pattern SP may be formed.

The sacrificial layer 120 may be formed of a material different from that of the semiconductor layer 130′. For example, the semiconductor layer 130′ may be formed of silicon, and the sacrificial layer 120 may be formed of silicon-germanium, silicon oxide, silicon nitride, silicon carbide, or silicon oxynitride. The sacrificial layer 120 may be formed to have a greater thickness in the Z-direction than the semiconductor layer 130′, but is not limited thereto.

The patterning process may include forming a separate mask pattern on the stack structure, etching the stack structure using the mask pattern as an etch mask, and removing the mask pattern. Through the patterning process, the semiconductor layers 130′ may be separated from each other in the Y-direction. Although not illustrated, the trenches and the insulating material layer may be formed between the semiconductor patterns 130 in FIG. 2.

The sacrificial plate pattern SP may be formed to pass through the stack structure and the insulating material layer filling the trenches. The sacrificial plate pattern SP may be formed in a direction intersecting the trenches. The sacrificial plate pattern SP may be formed to recess an upper portion of the lower structure 110, but is not limited thereto. The sacrificial plate pattern SP may have a line shape or a bar shape extending in the Y-direction in a plan view and may have a rectangular shape extending in a Y-Z plane in a cross-sectional view.

Referring to FIG. 12, a patterning process may be performed on the substrate 101 to form a first opening OP1 passing through the stack structure, the sacrificial layers 120 exposed through the first opening OP1 may be removed, a first insulating layer 121 and a second insulating layer 122′ may be sequentially formed between the semiconductor layers 130′, and the second insulating layer 122′ may be partially selectively removed from the first opening OP1 to form first gap regions G1.

The first opening OP1 may pass through the sacrificial layers 120 and the semiconductor layers 130′ in the Z-direction, and may have a via shape or a trench shape. Side surfaces of each of the sacrificial layers 120 and the semiconductor layers 130′ may be exposed through the first opening OP1.

The sacrificial layers 120 may be selectively removed with respect to the semiconductor layers 130′. While the sacrificial layers 120 are being removed, the semiconductor layers 130′ may be supported by an insulating material layer filling the trenches formed in FIG. 11.

A first insulating layer 121 may be formed in a space between the semiconductor layers 130′ to a predetermined thickness, and a second insulating layer 122′ may be formed on the first insulating layer 121 to fill the space. The second insulating layer 122′ may cover upper and lower surfaces of the semiconductor layers 130′ and may cover side surfaces of the sacrificial plate pattern SP. The first insulating layer 121 may not contact the sacrificial plate pattern SP.

A portion of the second insulating layer 122′ with respect to the semiconductor layers 130′ and the first insulating layer 121 may be selectively removed from the first opening OP1. The second insulating layer 122′ may be recessed from the side surface to form first gap regions G1 in the recessed space.

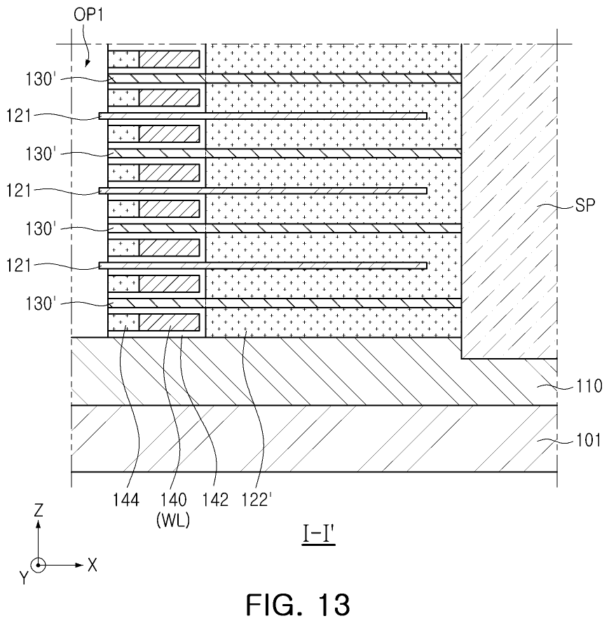

Referring to FIG. 13, a gate dielectric layer 142, a first conductive pattern 140, and a gate capping layer 144 may be formed in the first gap region G1.

The gate dielectric layer 142 may be conformally formed in the first gap region G1, an internal space of the first gap region G1 may be filled with a conductive material, and the conductive material may be partially removed from a side surface exposed to the first opening OP1 to form the first conductive pattern 140. The gate capping layer 144 may be formed in a region from which the conductive material is partially removed. Side surfaces of the gate dielectric layer 142, the gate capping layer 144, and the semiconductor layers 130′ may be coplanar with one another.

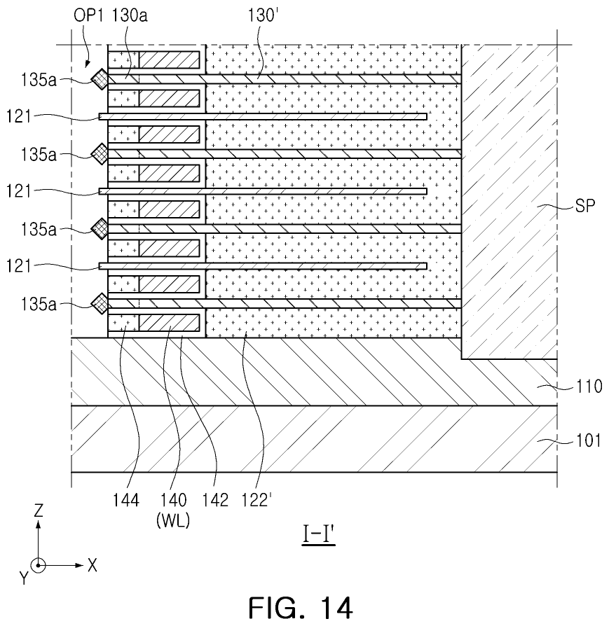

Referring to FIG. 14, an epitaxial growth process may be performed on the first end surface of the semiconductor layer 130′ to form a first epitaxial layer 135a. While the first epitaxial layer 135a is growing, impurities may be doped into the first epitaxial layer 135a through an in-situ doping process. Compared to a case in which lateral doping is performed on the semiconductor layer 130′, a dopant having a relatively high concentration may be smoothly implanted into the first epitaxial layer 135a. The implanted impurities may diffuse into a partial region of the semiconductor layer 130′ adjacent to the first epitaxial layer 135a by a heat treatment process, and a first impurity region 130a may be formed. The first epitaxial layer 135a may be formed in the shape of a facet grown according to a crystal plane of the semiconductor layer 130′, and the shape may be variously changed according to embodiments.

Referring to FIG. 15, a first metal-semiconductor compound layer 138a and a second conductive pattern 150 may be formed. The sacrificial plate pattern SP may be removed to form a second opening OP2, and the second insulating layer 122′ may be partially removed from the second opening OP2 to form second gap regions G2. A second epitaxial layer 135b may be formed by performing an epitaxial growth process on the second end surface of the semiconductor pattern 130 exposed through the second gap regions G2.

Forming the first metal-semiconductor compound layer 138a may include, for example, partially silicidazing or germanidizing the first epitaxial layer 135a. The first epitaxial layer 135a may react with a metal material or a metal nitride to form a first metal-semiconductor compound layer 138a in a portion thereof from the surface. The second conductive pattern 150 may be formed to extend vertically in the Z-direction.

A second opening OP2 may be formed in a region in which the sacrificial plate pattern SP is removed. The second opening OP2 may have a trench shape extending in the Y-direction, and side surfaces of the second insulating layer 122′ and the semiconductor layer 130′ may be exposed through the second opening OP2.

A portion of the second insulating layer 122′ with respect to the semiconductor layers 130′ and the first insulating layer 121 may be selectively removed from the second opening OP2. The second insulating layer 122′ may be recessed from the side surface to form second gap regions G2 in the recessed space.

While the second epitaxial layer 135b is growing, impurities may be doped into the second epitaxial layer 135b through an in-situ doping process. Compared to a case in which lateral doping is performed on the semiconductor pattern 130, a dopant having a relatively high concentration may be smoothly implanted into the second epitaxial layer 135b. The implanted impurities may diffuse into a partial region of the semiconductor pattern 130 adjacent to the second epitaxial layer 135b by a heat treatment process, and a second impurity region 130b may be formed. The shape of the second epitaxial layer 135b may also be variously changed according to embodiments. For example, in some embodiments, the second epitaxial layer 135b may be formed to have a shape different from that of the first epitaxial layer 135a.

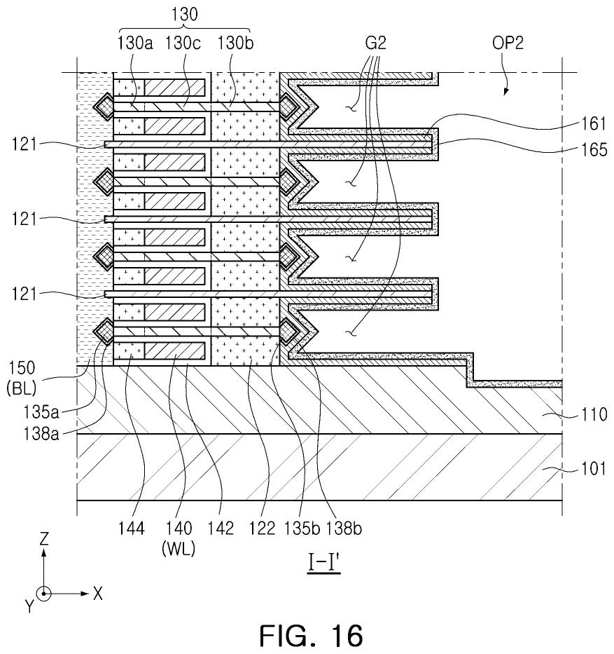

Referring to FIG. 16, a second metal-semiconductor compound layer 138b, a first electrode 161, and a dielectric layer 165 may be formed.

Forming the second metal-semiconductor compound layer 138b may include, for example, partially silicidating or germanidizing the second epitaxial layer 135b. The second epitaxial layer 135b may react with a metal material or a metal nitride to form the second metal-semiconductor compound layer 138b in a portion thereof from the surface.

After the first electrode 161 is conformally formed in the second gap regions G2, a portion thereof covering the end portion of the first insulating layer 121 may be partially removed to separate nodes between the first insulating layers 121. The dielectric layer 165 may be conformally formed on the first electrode 161. Thereafter, referring to FIG. 3, the second electrode 162 may be formed by filling the second gap regions G2 and the second opening OP2 with a conductive material. Accordingly, the capacitor CAP including the first electrode 161, the second electrode 162, and the dielectric layer 165 may be manufactured.

By disposing the epitaxial layer and the metal-semiconductor compound layer on at least one end of the semiconductor pattern, a semiconductor device having improved electrical characteristics and reliability may be provided.

The various and beneficial advantages and effects of the present inventive concept are not limited to the above, and will be more easily understood in the course of describing specific embodiments of the present inventive concept.

While example embodiments have been illustrated and described above, it will be apparent to those skilled in the art that modifications and variations could be made without departing from the scope of the present inventive concept as defined by the appended claims.

1. A semiconductor device comprising:
a plurality of semiconductor patterns stacked to be spaced apart from each other in a first direction, perpendicular to an upper surface of a substrate, and extending in a second direction, parallel to the upper surface of the substrate;
a plurality of first conductive patterns extending in a third direction, perpendicular to the first direction and the second direction, on the plurality of semiconductor patterns;
a plurality of second conductive patterns extending in the first direction on the substrate;
a plurality of capacitors, each of the plurality of capacitors electrically connected to a corresponding one of the plurality of semiconductor patterns; and
at least one epitaxial layer disposed to be in contact with at least one of both end surfaces of at least one of the plurality of semiconductor patterns and including an impurity.

2. The semiconductor device of claim 1, wherein the at least one epitaxial layer has a facet shape grown according to a crystal orientation of a semiconductor material layer of the semiconductor pattern.

3. The semiconductor device of claim 1, wherein the at least one epitaxial layer has a first side surface inclined with respect to an upper surface of the semiconductor pattern and a second side surface inclined with respect to a lower surface of the semiconductor pattern.

4. The semiconductor device of claim 3,
wherein an angle between the first side surface of the at least one epitaxial layer and the upper surface of the semiconductor pattern is an obtuse angle, and
wherein an angle between the second side surface of the at least one epitaxial layer and the lower surface of the semiconductor pattern is an obtuse angle.

5. The semiconductor device of claim 1,
wherein the plurality of first conductive patterns intersect the plurality of semiconductor patterns, respectively, and
wherein the plurality of second conductive patterns are disposed to be adjacent to first end surfaces of the plurality of semiconductor patterns.

6. The semiconductor device of claim 5, wherein the at least one epitaxial layer includes:
a plurality of first epitaxial layers disposed between first end surfaces of the plurality of semiconductor patterns and the plurality of second conductive patterns; and
a plurality of second epitaxial layers disposed between second end surfaces of the plurality of semiconductor patterns and the plurality of capacitors.

7. The semiconductor device of claim 6, further comprising:
a plurality of first metal-semiconductor compound layers disposed between the plurality of first epitaxial layers and the plurality of second conductive patterns, respectively; and
a plurality of second metal-semiconductor compound layers disposed between the plurality of second epitaxial layers and the plurality of capacitors, respectively.

8. The semiconductor device of claim 6, wherein the second conductive pattern has an inclined inner side surface facing an inclined side surface of each of the plurality of first epitaxial layers.

9. The semiconductor device of claim 5,
wherein each of the plurality of capacitors includes a first electrode, a dielectric layer on the first electrode, and a second electrode on the dielectric layer, and
wherein the first electrode covers the inclined side surface of a corresponding one of the plurality of second epitaxial layers, and includes a portion protruding toward the second electrode.

10. The semiconductor device of claim 1,
wherein the plurality of first conductive patterns are disposed to be adjacent to first end surfaces of the plurality of semiconductor patterns,
wherein the plurality of second conductive patterns intersect the plurality of semiconductor patterns, respectively, and
wherein the at least one epitaxial layer includes:
a plurality of first epitaxial layers disposed between first end surfaces of the plurality of semiconductor patterns and the plurality of first conductive patterns; and
a plurality of second epitaxial layers disposed between second end surfaces of the plurality of semiconductor patterns and the plurality of capacitors.

11. A semiconductor device comprising:
a plurality of structures and a plurality of first insulating layers alternately stacked on a substrate; and
a vertical conductive pattern extending vertically in a first direction, perpendicular to an upper surface of the substrate, on the substrate,
wherein each of the plurality of structures includes:
a capacitor including a capacitor electrode and a dielectric layer;
a semiconductor pattern including a first impurity region electrically connected to the vertical conductive pattern, a second impurity region electrically connected to the capacitor electrode, and a channel region between the first impurity region and the second impurity region;
a gate electrode disposed between the channel region of the semiconductor pattern and the plurality of first insulating layers and intersecting the vertical conductive pattern to extend in a second direction, parallel to the upper surface of the substrate;
at least one epitaxial layer disposed to be in contact with at least one of the first impurity region and the second impurity region of the semiconductor pattern and including an impurity having a concentration greater than both a concentration of the first impurity region and a concentration of the second impurity region;
a gate dielectric layer between the gate electrode and the semiconductor pattern;
a gate capping layer between the gate electrode and the vertical conductive pattern; and
a second insulating layer between the gate electrode and the capacitor electrode.

12. The semiconductor device of claim 11, wherein the at least one epitaxial layer has a cross-section having a triangle, a quadrangle, a pentagon, a hexagon, an octagon, a rhombus, a circle, or an ellipse.

13. The semiconductor device of claim 11, wherein each of the plurality of structures further includes at least one metal-semiconductor compound layer surrounding a surface of the at least one epitaxial layer.

14. The semiconductor device of claim 11, wherein a length between an upper end and a lower end of the at least one epitaxial layer is longer than a length between an upper surface and a lower surface of the semiconductor pattern in the first direction.

15. The semiconductor device of claim 11,
wherein the at least one epitaxial layer includes an impurity, and
wherein the impurity includes at least one of Ph, As, B, C, and Ga.

16. The semiconductor device of claim 11, wherein the at least one epitaxial layer extends from the first impurity region and overlaps the vertical conductive pattern in the first direction.

17. The semiconductor device of claim 11, wherein the at least one epitaxial layer extends from the second impurity region and overlaps the capacitor electrode in the first direction.

18. The semiconductor device of claim 11, wherein the first insulating layer extends to be longer than the second insulating layer horizontally.

19. A semiconductor device comprising:
a plurality of semiconductor patterns extending in a first direction parallel to an upper surface of a substrate and stacked to be spaced apart from each other on the substrate;
a conductive pattern intersecting the plurality of semiconductor patterns and extending in a second direction, perpendicular to the first direction;
a capacitor electrically connected to the semiconductor pattern;
an epitaxial layer extending from at least one end surface of the semiconductor pattern and having a vertical thickness thicker than a vertical thickness of the semiconductor pattern; and
a metal-semiconductor compound layer surrounding a surface of the epitaxial layer.

20. The semiconductor device of claim 19,
wherein the semiconductor pattern includes a channel region overlapping the conductive pattern and a first impurity region and a second impurity region disposed on sides of the channel region,
wherein the epitaxial layer includes an impurity, and
wherein an impurity concentration of the epitaxial layer is greater than an impurity concentration of the first impurity region and an impurity concentration of the second impurity region.

21.-25. (canceled)
